(19) United States
(12) Patent Application Publication
(10) Pub. No.: US 2026/0260030 A1
(43) Pub. Date: Sep. 3, 2026

(54) Facility Installation Management System

(71) Applicant: Daifuku Co., Ltd., Osaka-shi (JP)

(72) Inventors: Wataru Kiyokawa, Tokyo (JP); Asao Tsuchiya, Tokyo (JP); Ryouta Sugita, Tokyo (JP)

(21) Appl. No.: 19/551,758

(22) Filed: Feb. 27, 2026

(30) Foreign Application Priority Data
Feb. 28, 2025 (JP) 2025-031875

(51) Int. Cl. G06F 30/13; G06Q 10/08

(52) U.S. Cl. CPC G06F 30/13; G06Q 10/08

(57) ABSTRACT

A facility installation management system for installing a facility generates marking information based on a design drawing of the facility. The marking information is information indicating marks to be drawn on an installation surface, on which the facility is to be installed, to install a plurality of materials for the facility. The system draws an identification mark and an installation mark as the marks on the installation surface based on the marking information using a marking device movable along the installation surface. The identification mark indicates identification information identifying each of the plurality of materials. The installation mark indicates at least an installation position of each of the plurality of materials.

### CROSS-REFERENCE TO RELATED APPLICATION

This application claims priority to Japanese Patent Application No. 2025-031875 filed February 28, 2025, the disclosure of which is hereby incorporated by reference in its entirety.

### BACKGROUND OF THE INVENTION

### Field of the Invention

The present invention relates to a facility installation management system for installing a facility.

### Description of Related Art

Installation of a facility usually involves marking, or drawing a mark, performed on an installation surface of the facility. The facility with a larger scale uses more processes for the marking, increasing the period or the burden on the operators. In response to this, for example, Japanese Unexamined Patent Application Publication No. 2020-139273 describes an automatic marking technique using a marking device movable along the installation surface. The marking device draws positions at which materials are to be installed, such as the positions of ends of a single drawn line, the position of an intersection of drawn lines in a cross shape, the position of a junction of drawn lines in a T shape, and the position of a corner of drawn lines in an L shape.

The marking operation performed using the marking device reduces the period for installing a facility or reduces the operation burden. However, the marking operation still uses many processes performed with reference to the design drawing, such as a process of selecting materials to be installed at the position instructed by marking or a method for installing the materials.

### SUMMARY OF THE INVENTION

In response to the above, techniques are awaited for automatic marking including more design information items than known marking.

A facility installation management system responding to the above is a facility installation management system for installing a facility. The system generates marking information based on a design drawing of the facility. The marking information is information indicating marks to be drawn on an installation surface to install a plurality of materials for the facility. The installation surface is a surface on which the facility is to be installed. The system draws an identification mark and an installation mark as the marks on the installation surface based on the marking information using a marking device movable along the installation surface. The identification mark indicates identification information identifying each of the plurality of materials. The installation mark indicates at least an installation position of each of the plurality of materials.

The marking device with this structure draws, on an installation surface on which materials are to be installed, arrangement marks indicating, for example, position information and identification marks of the materials. The marking information for such marking is generated based on a design drawing, and thus can reduce the frequency of the operators referring to the design drawing during the facility installation work. The marking device with this structure can thus perform automatic marking including more design information items than known marking.

Further features and advantageous effects of the facility installation management system will be apparent from exemplary and nonlimiting embodiments described below with reference to the drawings.

### BRIEF DESCRIPTION OF THE DRAWINGS

FIG. 1 is a perspective view of an example article storage facility.

FIG. 2 is a schematic diagram of an example facility installation management system.

FIG. 3 is a diagram illustrating identification of the position of a marking device.

FIG. 4 is a diagram illustrating correction of the position of a portion marked by the marking device.

FIG. 5 is a schematic diagram of an example facility installation management system using feedback information from the marking device.

FIG. 6 is a diagram of example drawn marks.

FIG. 7 is a diagram of example drawn marks.

FIG. 8 is a diagram of example drawn marks.

FIG. 9 is a diagram of example drawn marks.

FIG. 10 is a diagram of example drawn marks.

FIG. 11 is a diagram of example drawn marks.

### DESCRIPTION OF THE INVENTION

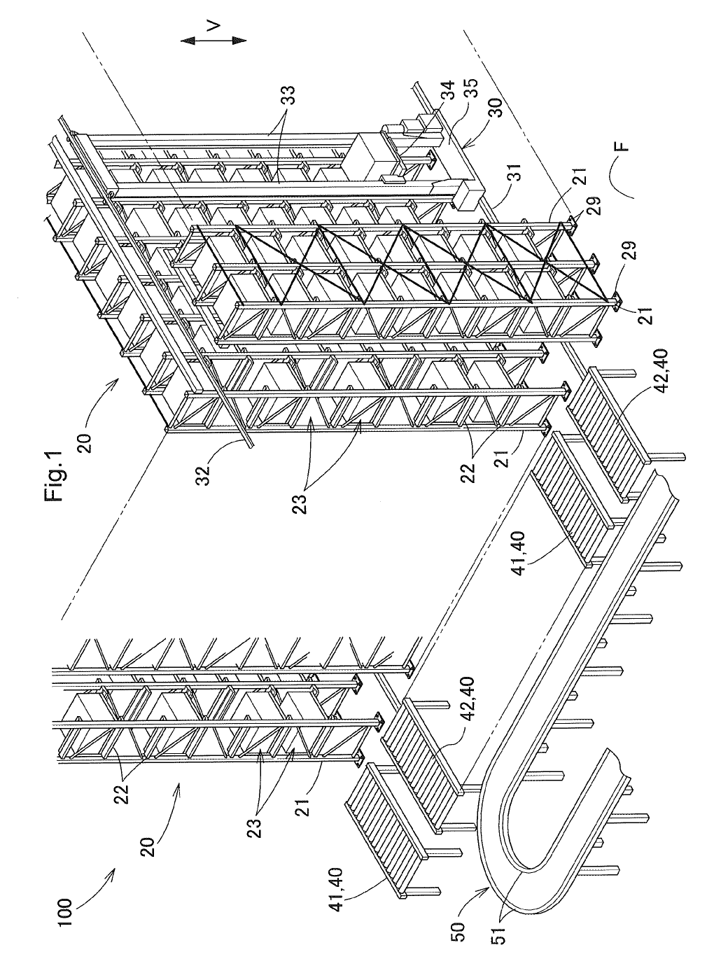

A facility installation management system according to one or more embodiments will be described below with reference to the drawings. An article storage facility 100, as shown in the perspective view in FIG. 1, is illustrated as a facility to be installed. As shown in FIG. 1, the article storage facility 100 includes article storage racks 20 for storing articles, a stacker crane 30, and multiple conveyors 40. However, the facility to be installed is not limited to the article storage facility 100. In some embodiments, the facility to be installed may be an article storage facility including vertically movable lifters and horizontally movable transport vehicles, an article transport facility that transports articles using conveyors or transport vehicles, or an article sorting device that transports articles while sorting the articles.

The article storage rack 20 includes multiple storage portions 23 for storing articles. In the article storage facility 100 according to the present embodiment, two article storage racks 20 opposing across the stacker crane 30 form a single storage unit. Each article storage rack 20 includes multiple posts 21 standing on a facility installation surface F (e.g., a floor surface of a building) at predetermined intervals in the horizontal direction and multiple shelf boards 22 fixed to the posts 21 at predetermined intervals in a vertical direction V to support articles. Each storage portion 23 for storing an article is defined by a space above the shelf boards 22 fixed at the same level to the corresponding one of the multiple posts 21. The storage portions 23 are arranged adjacent to one another in the direction perpendicular to a travel rail 31 serving as a travel path of the stacker crane 30. The stacker crane 30 held between a pair of article storage racks 20 can transfer articles to and from the article storage racks 20.

Adjacent to a first end of the article storage rack 20 in a direction in which the storage portions 23 are arranged, a conveyor 40 (loading conveyor 41) for loading articles onto the article storage racks 20 and a conveyor 40 (unloading conveyor 42) for unloading articles from the article storage racks 20 are arranged. As shown in FIG. 1, the loading conveyor 41 is disposed adjacent to one of the article storage racks 20 opposing across the stacker crane 30, and the unloading conveyor 42 is disposed adjacent to the other of the opposing article storage racks 20. Each conveyor 40 is, for example, a roller conveyor, a slat conveyor, or a belt conveyor. As shown in FIG. 1, the article storage facility 100 may further include another transport device 50 for supplying articles to the loading conveyor 41 or for receiving articles from the unloading conveyor 42.

The function of each conveyor 40 may not be a loading or unloading function. Each conveyor 40 may function as the loading conveyor 41 or the unloading conveyor 42 as appropriate. For example, when many articles are to be loaded onto the article storage racks 20, both conveyors 40 may function as the loading conveyors 41, and when many articles are to be unloaded from the article storage racks 20, both conveyors 40 may function as the unloading conveyors 42.

The stacker crane 30 installed between the pair of opposing article storage racks 20 moves along the travel rail 31 installed along the front surfaces of the article storage racks 20, and transports articles between the loading conveyor 41 and each article storage rack 20, between different storage portions 23 in the same article storage rack 20, between one of the article storage racks 20 and another article storage rack 20, and between each article storage rack 20 and the unloading conveyor 42.

The stacker crane 30 includes a travel cart 35 that travels on the travel rail 31 installed on the installation surface F, a pair of masts 33 standing on the travel cart 35, and a lifter 34 that ascends and descends along the pair of masts 33 in the vertical direction V. The lifter 34 includes a transfer device that transfers articles between each storage portion 23 and the stacker crane 30. The upper ends of the pair of masts 33 are guided by a guide rail 32 installed on the ceiling. The lifter 34 ascends and descends along the masts 33 to move to a position to face a predetermined storage portion 23. The transfer device included in the lifter 34 transfers articles between each storage portion 23 and the stacker crane 30.

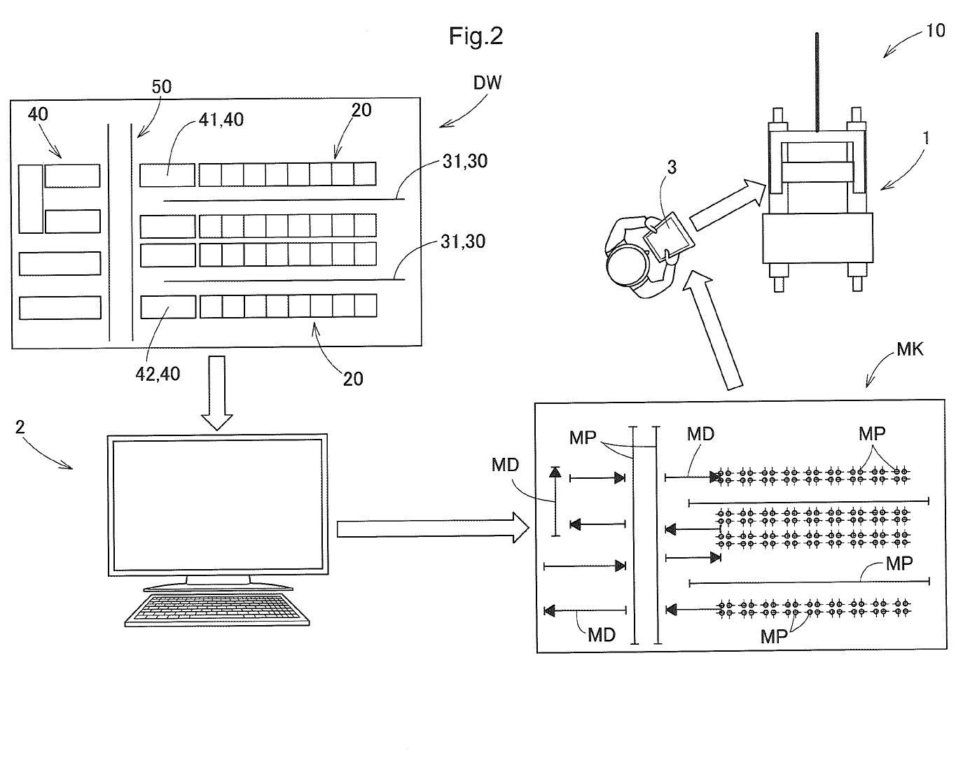

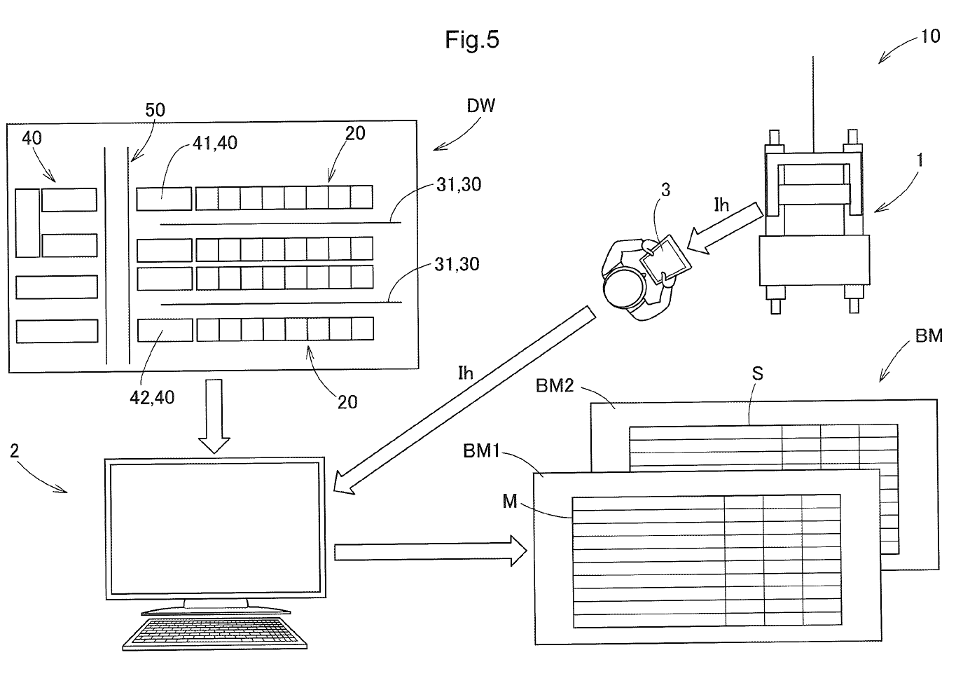

FIG. 2 is a schematic diagram of an example of a facility installation management system 10. The figure illustrates an example operation procedure for installing the above article storage facility 100. The facility installation management system 10 includes at least one computer 2 (controller) and a program (application software) executable on the computer 2. In the present embodiment, the facility installation management system 10 further includes a tablet 3 (mobile terminal) carried by an operator. The facility installation management system 10 cooperates with a marking device 1. The marking device 1 autonomously moves over the installation surface F, and automatically performs marking on the installation surface F. Marking is an operation of drawing marks on the installation surface F for arranging materials M (refer to FIG. 5; e.g., the posts 21) for the facility on the installation surface F.

To install the article storage facility 100, a designer creates a design drawing DW using a design drawing program (computer aided design or CAD). To install the article storage facility 100, the same or a different design drawing program is used to generate, based on the design drawing DW, marking information MK indicating marks to be drawn on the installation surface F to install the multiple materials M for the facility on the installation surface F, and outputs the marking information MK. When generating the marking information MK based on the design drawing DW, the design drawing program may use all information items as marking information, but excess information items drawn on the installation surface F lower viewability. The design drawing program thus selects only information items to be drawn on the installation surface F, and generates the marking information MK.

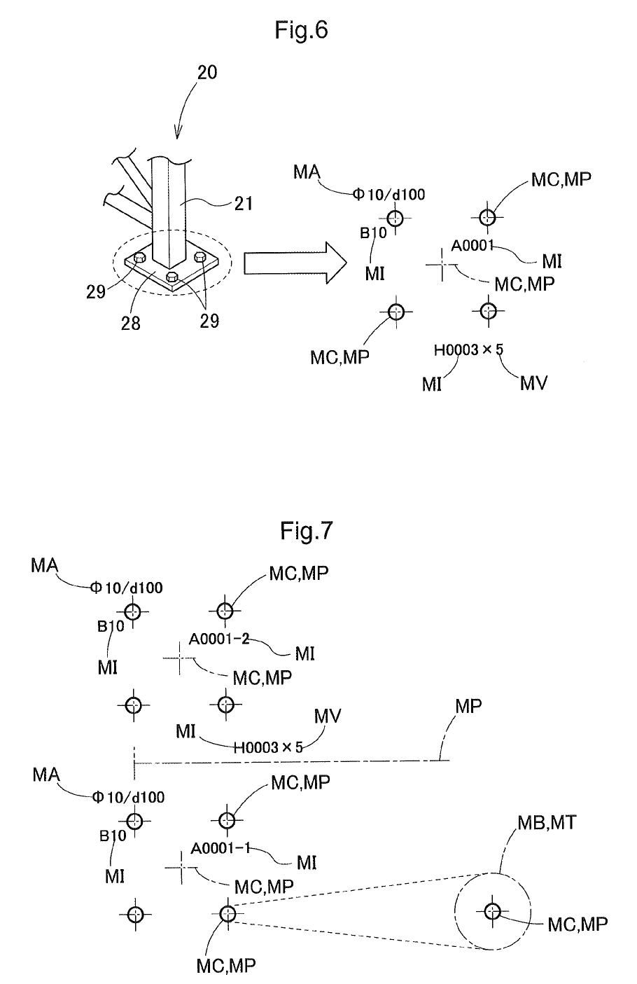

As described in detail with reference to FIG. 6 and other figures later, the marking information MK includes identification marks MI indicating unique identification information items for identifying the materials M, and installation marks MP at least indicating the positions at which the materials M for the article storage facility 100 are to be arranged. As described later, the installation marks MP may include orientation marks MD indicating the orientations of the materials M and position marks MC indicating the positions of the materials M. Multiple information items may be drawn with a single mark. More specifically, a single installation mark MP may include information about the installation position and information about the material orientation.

For example, the marking information MK is transferred from the computer 2 to the tablet 3 carried by an operator at the site at which the facility is installed. The operator outputs the marking information MK to the marking device 1 through a marking device control program (application software) executed on the tablet 3. The marking information MK may be directly transferred from the computer 2 to the marking device 1, or output from the computer 2 to the cloud, and the marking information MK stored on the cloud may be downloaded by the marking device 1. In some embodiments, the marking information MK may be output from the computer 2 to a storage medium such as a memory card, and the marking device 1 may obtain the marking information MK by mounting the storage medium on the marking device 1.

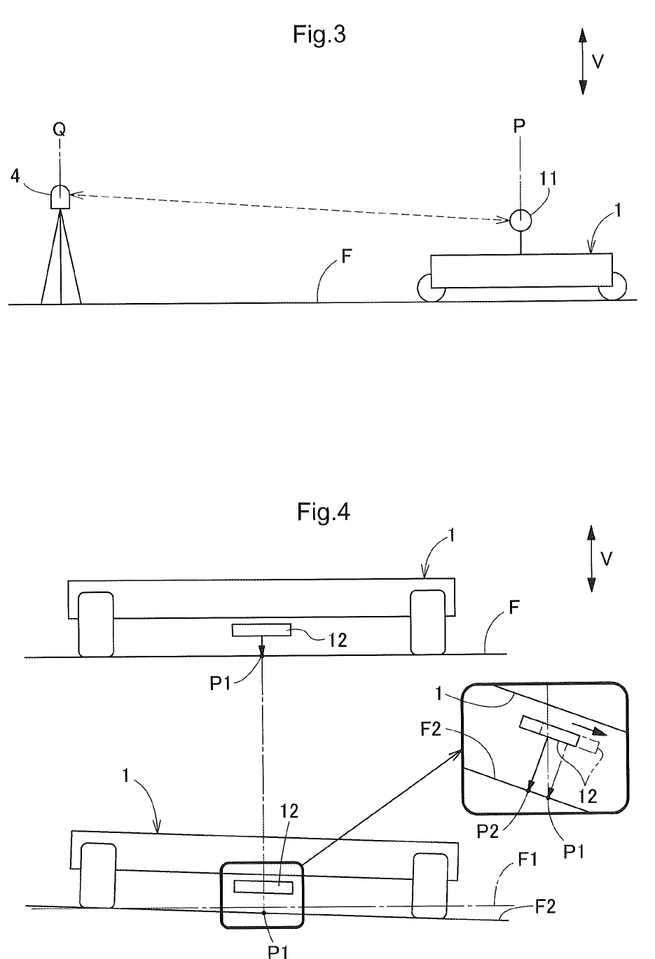

As shown in FIG. 3, a reference definer 4 that defines a three-dimensional reference position Q is disposed on the installation surface F. The marking device 1 includes a light receiver 11 that receives a laser beam emitted from the reference definer 4. The marking device 1 identifies its position (device position P) in a space in which the facility is installed based on a relative position with respect to the reference definer 4. To draw (to perform an operation including printing; the same applies hereafter) a mark at the position defined by the marking information MK on the installation surface F, the marking device 1 stops at the device position P corresponding to the position. The marking device 1 includes a printer head 12 supported by an XY table device (not shown). While stopping, the marking device 1 draws a mark set by the marking information MK on the installation surface F by moving the printer head 12.

The light receiver 11 includes a prism, and detects the three-dimensional positions of multiple portions of the marking device 1, for example, four corners. When the positions of multiple portions of the marking device 1 are identified, the marking device 1 can determine the inclination of the installation surface F as shown in FIG. 4. FIG. 4 shows a state in which an actual installation surface F2, which is the actual installation surface F, drawn by a solid line is inclined with respect to an ideal installation surface F1, which is a designed installation surface F, drawn by a dot-dash line. A position P1 of a mark (installation mark MP, particularly, position mark MC) drawn on the installation surface F by the marking device 1 is defined in the marking information MK with respect to the ideal installation surface F1. When the installation surface F is inclined, the position P1 of the mark deviates to the position P2. The marking device 1 draws a mark at the correct position P1 by adjusting the position of the printer head based on the inclination of the installation surface F. As described above, the printer head 12 is movable. Thus, the position at which the mark is drawn can be corrected from P2 to P1 by moving the printer head 12 based on the inclination of the installation surface F.

The marking device 1 can obtain information about the level of the actual installation surface F at the position at which a mark is drawn and the inclination is detected, or more specifically, at the position at which each material M is to be installed. The marking device 1 generates installation surface level information Ih (refer to FIG. 5) indicating the level of the installation surface F at planar positions (may be an absolute position or a deviation from the virtual plane parallel to the horizontal plane).

When the actual installation surface F2 is lower than the ideal installation surface F1 as shown in FIG. 4, an adjuster S (refer to FIG. 5) may be used to install the material M by adjusting the level of the installation surface F. The adjuster S is, for example, a shim. Such an adjuster is usually selected as appropriate by an operator at the facility installation site and is used. However, the type and the number of adjusters S to be used can be identified before the installation work based on the installation surface level information Ih generated by the marking device 1.

As shown in FIG. 5, for example, the installation surface level information Ih can be fed back to the computer 2 from the marking device 1 through the tablet 3. The installation surface level information Ih may be directly transferred from the marking device 1 to the computer 2, or the installation surface level information Ih may be output from the marking device 1 to the cloud, and the installation surface level information Ih stored on the cloud may be downloaded by the computer 2. In some embodiments, the installation surface level information Ih may be output from the marking device 1 to a storage medium such as a memory card, and the computer 2 may obtain the installation surface level information Ih by mounting the storage medium on the marking device 1.

The computer 2 outputs the type and the number of adjusters S used to install the materials M for the entire facility based on the facility design drawing DW and the installation surface level information Ih. More specifically, the computer 2 generates a component table of the adjusters S (adjuster component table BM2) to allow the contractor to prepare for the installation including placing an order of appropriate adjusters S based on the adjuster component table BM2 after the marking is complete and before the facility installation work is started. Typically, more than expected number of adjusters S are prepared to allow selections at the site, and unused adjusters S are discarded. In contrast, the adjuster component table BM2 allows preparation that reduces wastes and costs.

In the example illustrated in FIG. 5, a material component table BM1 in which the type and the number of facility materials M are set and an adjuster component table BM2 in which the type and the number of adjusters S are set are generated based on a program executed on the computer 2. In some embodiments, a single component table including information about the materials M and the adjusters S may be generated.

In another example, a database on the adjusters S, which are typically general-purpose components, may be stored in the marking device 1 or the tablet 3. Instead of determining the type and the number of adjusters S with the computer 2 by feeding back the installation surface level information Ih from the marking device 1 to the computer 2, the type and the number of adjusters S may be determined with the marking device 1 or the tablet 3 (more specifically, at the facility installation site). In this case, information about the type and the number of adjusters S (adjuster information) may be fed back to the computer 2 together with the installation surface level information Ih, or information about the type and the number of adjusters S may be added to the installation surface level information Ih and fed back to the computer 2. The computer 2 generates the above component table based on the feedback information. When the computer 2 does not determine the type and the number of adjusters S based on the installation surface level information Ih, the adjuster information alone may be fed back from the marking device 1 to the computer 2 and reflected on the component table.

The marks drawn on the installation surface F will now be described. FIG. 6 illustrates marks drawn on the installation surface F to install a post 21 in the article storage rack 20 shown in FIG. 1. An identification mark MI indicating unique identification information is associated with the post 21. A mark A0001 as an identification mark MI is associated with the post 21 in this example. The facility includes multiple posts 21, and thus assigning a unique identification information item to each post 21 allows easy allocation of the materials M. An installation mark MP indicating the center position of each post 21 with an intersection of a cross mark is drawn on the installation surface F. This mark also serves as a position mark MC indicating the installation position of the post 21.

Each post 21 is installed on the installation surface F with bolts 29 fastening a fastening portion 28 to the installation surface F. As shown in FIG. 6, one post 21 is fastened to the installation surface F with four bolts 29. The installation marks MP are drawn at the positions at which the bolts 29 are installed. These marks also correspond to position marks MC indicating the bolt positions. In addition, a mark B10 is drawn as the identification mark MI associated with the bolts 29. Multiple subsidiary materials used for a single material M and used commonly for the multiple materials M, such as the bolts 29, may be marked with an identification mark indicating common identification information about the type of materials, rather than with unique identification information. This can reduce the amount of marks on the installation surface F.

The four bolts 29 are of the same type, and a single mark is thus drawn near one of the bolts 29. The drawn mark is an installation mark MP (position mark MC) indicating the position at which the bolt 29 is to be disposed and an identification mark MI identifying the type of bolt 29. The bolt 29 is placed through a bolt hole formed in the installation surface F during the installation work. A processing mark MA indicating the processing information is thus also drawn as a mark relating to the bolt 29.

In the present embodiment, as shown in FIG. 6, the installation mark MP (position mark MC) is drawn as a mark indicating the center position with an intersection of a cross mark. In the present embodiment, a circle corresponding to the diameter of the bolt hole is also marked as a part of the installation mark MP. In addition, a mark φ10/d100 is drawn as a processing mark MA near the installation mark MP. This mark is an instruction for forming a bolt hole with a diameter of 10 mm and a depth of 100 mm. The circular mark corresponding to the hole diameter in the above installation mark MP may also have at least one of the functions of the processing mark MA. Installing the materials M on the installation surface F may involve processing on the installation surface F such as drilling a bolt hole or an anchor hole. As described above with reference to FIG. 6, drawing the processing information on the installation surface F allows the operator to perform processing on the installation surface F without referring to the design drawing, easily improving working efficiency.

The processing information indicating information about processing performed on the installation surface F may include other information items such as tolerance in addition to the hole diameter and the hole depth described above. Although not specifically described, the processing mark MA may be drawn in a manner different from the manner used in the illustrated example based on the processing information.

As in the article storage facility 100 described above as an example facility with reference to FIG. 1, the facility includes the materials M directly installed on the installation surface F, such as the posts 21, and the materials M installed on the materials M installed on the installation surface F, such as the shelf boards 22. To distinguish these materials M, the materials M directly installed on the installation surface F are referred to as directly installed materials, and the materials M attached to the directly installed materials are referred to as indirectly installed materials.

The posts 21 are examples of the directly installed materials, and the shelf boards 22 are examples of the indirectly installed materials. A single directly installed material such as the post 21 is installed at a single position on the installation surface F, but multiple indirectly installed materials such as the shelf boards 22 may be installed at a single position on the installation surface F. The information about the indirectly installed materials may be drawn on the installation surface F in a manner associated with the mark of the corresponding directly installed material. This can easily improve the working efficiency for preparing materials for the installation work. In the example illustrated in FIG. 6, marks of such indirectly installed material are also drawn.

A mark H0003 in FIG. 6 is a unique identification mark MI indicating the shelf board 22 to be disposed at this position, and a mark 5 is a quantity mark MV indicating use of five shelf boards 22. The five shelf boards 22 arranged at the same position on the installation surface F are assigned with the same identification information. The identification mark MI and the quantity mark MV of the shelf board 22, which is an indirectly installed material, are drawn near the installation mark MP of the post 21, which is a directly installed material. More specifically, the identification mark MI indicating an indirectly installed material and the quantity information (quantity mark MV) indicating the number of indirectly installed materials to be used are drawn in a manner associated with a mark (such as an installation mark MP) indicating a directly installed material.

The indirectly installed materials such as the shelf boards 22 may not be assigned with unique identification information based on the installed location. For example, the same materials M such as the shelf boards 22 with the same length may be assigned with the same identification information.

As shown in FIG. 1, the shelf boards 22 are supported by the multiple posts 21. In the example illustrated in FIG. 7, the marks indicating the relationship between the shelf boards 22 and two of the multiple posts 21 that support the shelf boards 22 are drawn on the installation surface F. The marks relating to the posts 21 are the same as described above with reference to FIG. 6. The two posts 21 have different identification marks MI. In this example, one of the posts 21 has an identification mark MI of A0001-1, and the other of the posts 21 has an identification mark MI of A0001-2.

In the example illustrated in FIG. 6, marks relating to the shelf boards 22, which are indirectly installed materials, simply include the identification mark MI and the quantity mark MV. In the example illustrated in FIG. 7, the installation mark MP of the shelf boards 22 is also drawn on the installation surface F. The installation mark MP corresponding to the shelf board 22 is drawn with a dot-dash line indicating the center line passing the end of the short side of the rectangular shelf board 22 and passing the middle of the short side along the long side. Although not shown in FIG. 7, the installation mark MP includes lines indicating both ends of the short sides of the shelf board 22 and a center line connecting the middles of both ends of the short sides. The operator can install the shelf boards 22 on the posts 21 with reference to the installation mark MP. To arrange multiple shelf boards 22 while having their short sides facing each other, the installation mark MP clearly shows the boundary between the materials M, and facilitates the installation work. In this example, as shown in FIG. 7, the identification mark MI and the quantity mark MV of the shelf board 22 may be drawn near the installation mark MP of the shelf board 22, which is an indirectly installed material.

The mark H0003 in FIG. 6 corresponds to a unique identification mark MI indicating the shelf board 22 to be disposed at this position, and the mark 5 corresponds to a quantity mark MV indicating use of five shelf boards 22. The five shelf boards 22 arranged at the same position on the installation surface F are assigned with the same identification information. The identification mark MI and the quantity mark MV of the shelf boards 22, which are indirectly installed materials, are drawn near the installation mark MP of the post 21, which is a directly installed material. More specifically, the identification mark MI indicating indirectly installed materials and the quantity information (quantity mark MV) indicating the number of the indirectly installed materials to be used are drawn in a manner associated with a mark (such as an installation mark MP) indicating a directly installed material.

The indirectly installed materials such as the shelf boards 22 may not be assigned with unique identification information based on the installed location. For example, the same materials M such as the shelf boards 22 with the same length may be assigned with the same identification information.

Either in the same manner as the indirectly installed materials or as the indirectly installed materials, the above adjusters S may have, in a manner associated with the corresponding directly installed material, the identification mark MI and the quantity mark MV drawn on the installation surface F. The identification mark MI indicates the identification information including at least the type of adjuster S used. As described above, when the marking device 1 can set the type or the number of adjusters S, the marking device 1 can set the identification mark MI and the quantity mark MV relating to the adjuster S, and draw marks relating to the adjuster S when marks relating to the corresponding directly installed material are to be drawn. To set the type or the number of adjusters S with the tablet 3, the marking device 1 communicates with the tablet 3 while marking, and thus can draw marks relating to the adjuster S while drawing marks relating to the corresponding directly installed material. When the installation surface level information Ih is fed back to the computer 2 to determine the type and the number of adjusters S, the marking information MK for each adjuster S is separately generated and transferred to the marking device 1 to draw only the marks relating to the adjuster S. Thus, marking for the adjuster S can be performed.

As shown in FIGS. 6 and 7, the processing mark MA for a bolt hole is also drawn for the bolt 29. For a portion to be processed during installation of the materials M, a mark indicating information about the processing accuracy may also be drawn. For example, a bolt hole is formed using a drill or other tools. When the installation surface F is formed from a material such as concrete, for example, the opening of the bolt hole in the installation surface F may be chipped. When adjacent bolt holes are chipped at portions facing each other, these two bolt holes may be connected. The bolt holes may thus be arranged at appropriate intervals. In addition to the bolt hole, a buffer area not allowing other processing may be saved around each bolt hole. As shown in an enlarged diagram in FIG. 7, a buffer area mark MB indicating the buffer area may be drawn in a manner associated with the installation mark MP of the bolt 29. The buffer area mark MB may also be referred to as an accuracy mark MT indicating the processing accuracy or the installation accuracy.

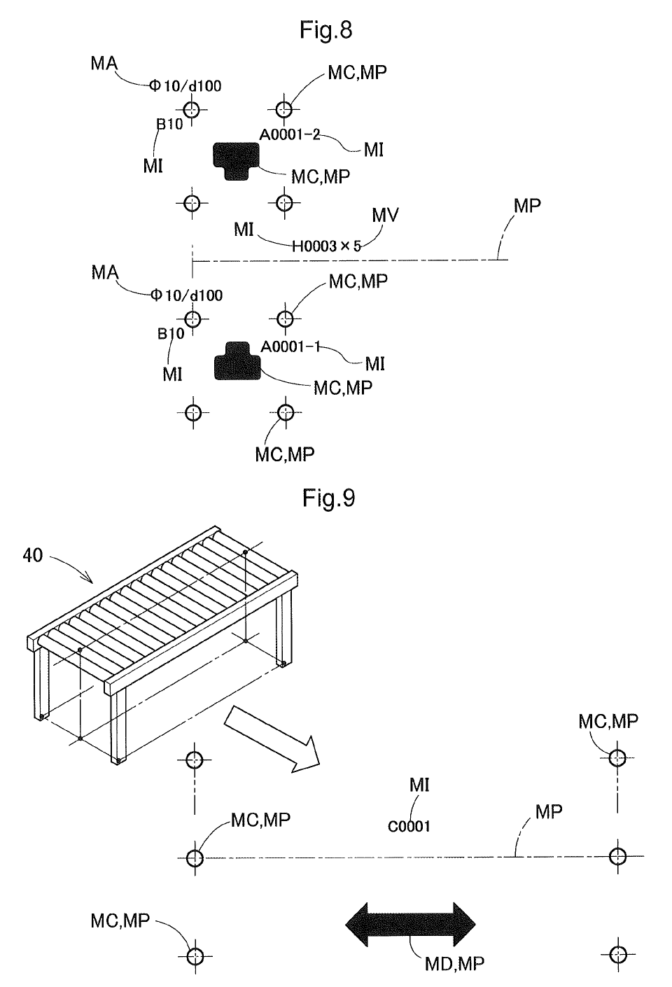

The installation orientation of each material M may be specified. In the example illustrated in FIG. 8, the installation mark MP is drawn with a cross section of the post 21. For the fastening portion 28 with a square or rectangular shape to which the bolts 29 are attached, the fastening portion 28 may be mounted on the installation surface F with the post 21 facing in an orientation different from the specified orientation. Drawing the orientation of each post 21 on the installation surface F with the installation mark MP facilitates installation of the post 21 in a correct orientation.

FIG. 9 illustrates example marks used to install an assembly (device) such as the conveyor 40 on the installation surface F. Marks such as the installation mark MP, the position mark MC, and the identification mark MI are the same as those described above with reference to FIGS. 6 to 8. Although the conveyor 40 is described in this example, the center line extending in the transport direction for the conveyor 40 may also be drawn on the installation surface F as the installation mark MP, in the same manner as for the shelf board 22. Drawing the installation mark MP indicating the center line facilitates identification of a transport path of articles, allowing easy determination on the likelihood of interference with other components, such as a shutter, in the facility.

For the conveyor 40, the transport direction in which the conveyor 40 transports articles may be drawn as the orientation mark MD. Although the transport direction is bidirectional in the example illustrated in FIG. 9, the transport direction of some conveyors 40 may be unidirectional. In this case, drawing the orientation mark MD facilitates installation of the conveyor 40 in the correct transport direction.

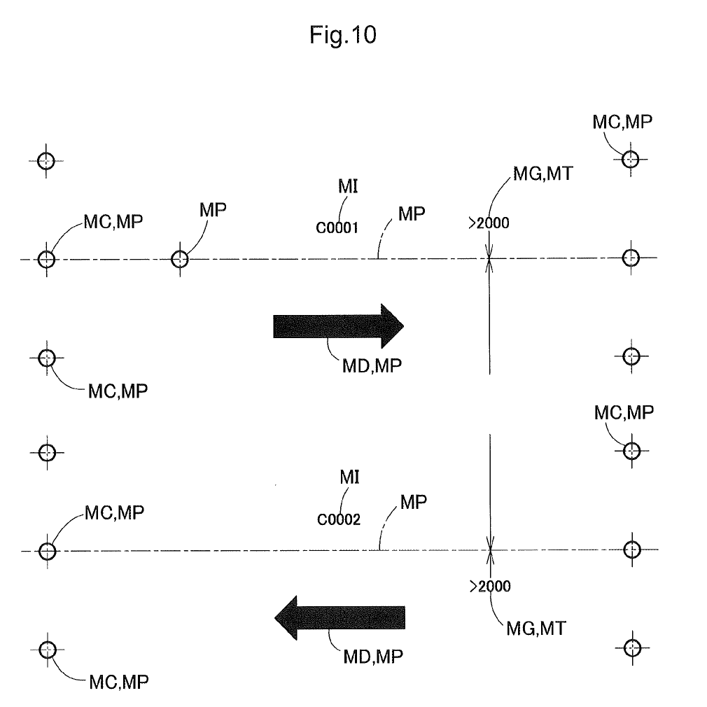

As illustrated in the design drawing DW in FIG. 2, the conveyors 40 such as the loading conveyor 41 and the unloading conveyor 42 may be arranged adjacent to each other in the article storage facility 100 in FIG. 1. In particular, the interval between the conveyors 40 arranged adjacent to the two article storage racks 20 adjacent to each other without the stacker crane 30 interposed between the article storage racks 20 is shorter than the interval between the conveyors 40 arranged adjacent to the two article storage racks 20 adjacent to each other with the stacker crane 30 interposed between the article storage racks 20. To avoid, for example, interference between the transported articles, the conveyors 40 are to be arranged with appropriate accuracy. As shown in FIG. 10, for example, a mark (interval mark MG) indicating the distance (2000 mm or more in this example) from the adjacent conveyor 40 may be drawn on the installation surface F in a manner associated with the installation mark MP indicating the center line of the conveyor 40. The interval mark MG may also be referred to as an accuracy mark MT indicating installation accuracy.

The installation accuracy information indicating the installation accuracy may include information about straightness of the travel rail 31, in addition to the examples shown in FIGS. 7 and 10.

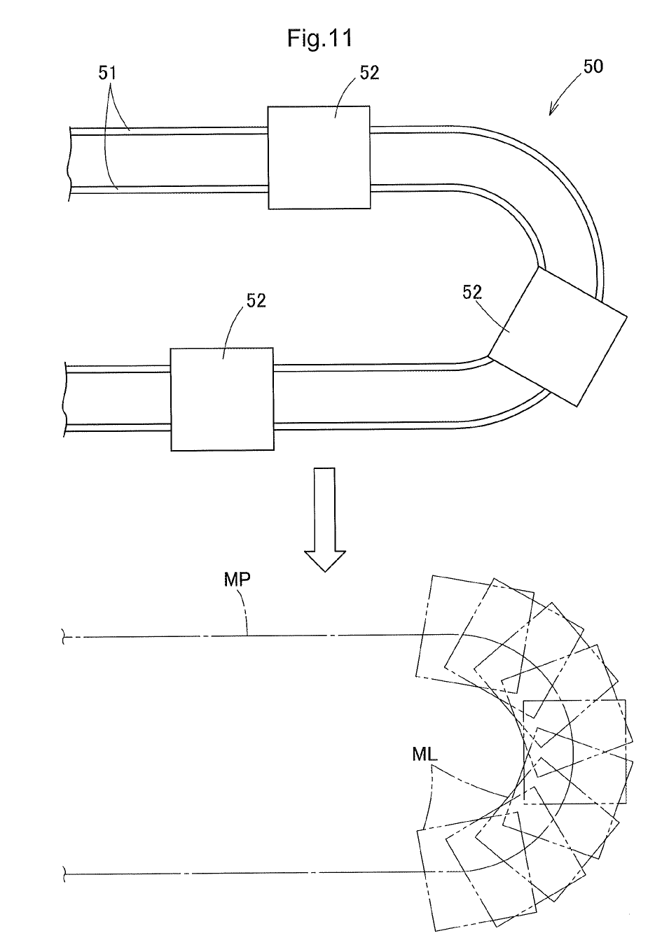

As shown in FIG. 1, the transport device 50 may have a curved transport path. FIG. 11 illustrates the transport device 50 that transports articles with transport vehicles 52 movable along a predetermined transport path. In the present embodiment, the transport device 50 includes transport vehicles 52 that travel on rails 51 serving as a transport path. When each transport vehicle 52 travels along curves of the rails 51, the movement path of the profile of the transport vehicle 52 is less easily predictable than when the transport vehicle 52 travels along straight portions. To install the transport device 50 on the installation surface F, the movement paths of the transport vehicles 52 are to be appropriately provided to the operator performing the installation work to avoid, for example, interference between the transport vehicles 52 and the operator in the facility or interference between the transport articles and other installed objects in the facility. As shown in FIG. 11, a mark (movement path mark ML) indicating at least one of a movement path of the transport vehicle 52 in the curved area of the transport path (rails 51) in the transport device 50 or a movement path of an article transported by the transport vehicle 52 (particularly, when the article is transported while protruding outward from the transport device 50 in a direction perpendicular to the movement direction of the transport device 50) may be drawn on the installation surface F in a manner associated with the installation mark MP for positioning the transport device 50.

As described above with various marks as examples, assigning unique identification information to the materials M, attaching a label indicating the identification information to the materials M, and drawing the identification mark MI corresponding to the identification information about the installation surface F allow arrangement of the materials M at appropriate locations without reference to the design drawing DW or the material component table BM1 during the installation work.

As illustrated in FIGS. 6 to 11, the marking device 1 may draw the installation mark MP indicating the center line of the conveyor 40 or the shelf board 22 as a long material M, or the movement path mark ML indicating the movement path of the transport vehicle 52 with, for example, a dashed line, a dot-dash line, or a two-dot-dash line, rather than with a continuous line. The marking device 1 can thus reduce ink fading or ink consumption during drawing.

For the bolt holes, marks may have different shapes, different colors, or both based on the hole diameter, the hole depth, or other factors. In some embodiments, the marks may have, for example, different colors for different sections of the installation work. When one stacker crane 30, two article storage racks 20, and two conveyors 40 for loading and unloading articles are included in each storage unit in the article storage facility 100 shown in FIG. 1, for example, marks may be drawn with different colors for different storage units.

Although specific marks are not shown, the level of the transport surface of, for example, the conveyor 40 may be drawn on the installation surface F. For example, the materials M separately include a member forming the transport surface (transport surface member) and members supporting the transport surface member (leg members), and these members are assembled into the conveyor 40 at the installation site. In such a case, a mark similar to the mark for the posts 21 is drawn on the installation surface F for the leg members. The transport surface member attached to the leg members may be referred to as an indirectly installed material. The identification mark MI may be drawn on the installation surface F in a manner associated with the leg members, and the level at which the transport surface member is attached to the leg members may be drawn with a mark on the installation surface F.

In addition to indicating the materials M for a facility, marking may be performed to indicate an area in which no materials M is to be installed. For example, marks indicating information to demarcate the installation surface F, such as an area reserved for additional equipment or an installation prohibited area saved for an evacuation route, may be drawn. When information about, for example, piping installed under the installation surface F is known, the positions of the piping may be drawn on the installation surface F.

An overview of the facility installation management system described above is briefly provided below.

In one aspect, a facility installation management system is a facility installation management system for installing a facility. The system generates marking information based on a design drawing of the facility. The marking information is information indicating marks to be drawn on an installation surface to install a plurality of materials for the facility. The installation surface is a surface on which the facility is to be installed. The system draws an identification mark and an installation mark as the marks on the installation surface based on the marking information using a marking device movable along the installation surface. The identification mark indicates identification information identifying each of the plurality of materials. The installation mark indicates at least an installation position of each of the plurality of materials.

The marking device with this structure draws, on an installation surface on which materials are to be installed, arrangement marks indicating, for example, position information and identification marks of the materials. Marking information for such marking is generated based on a design drawing, and thus can reduce the frequency with which the operators refer to the design drawing during the facility installation work.

In the facility installation management system, the installation mark may further indicate at least one of a shape or an orientation of each of the plurality of materials.

In this structure, the marks drawn on the installation surface allow the operator to easily identify installed materials or the installation orientation, easily improving the working efficiency.

In the facility installation management system, the plurality of materials may include a directly installed material to be installed directly on the installation surface and an indirectly installed material to be attached to the directly installed material. The system may draw, in a manner associated with the marks indicating the directly installed material, the identification mark indicating the indirectly installed material and quantity information indicating a number of the indirectly installed material to be used.

Multiple indirectly installed materials may be installed at a single position of the installation surface corresponding to a single directly installed material installed at the same position of the installation surface. In this structure, the quantity information of the indirectly installed materials attached to the directly installed material is marked in a manner associated with the mark of the directly installed material to which the indirectly installed materials are attached. This easily improves the working efficiency for preparing materials for the installation work.

The facility installation management system may further draw, on the installation surface, processing information indicating information about processing to be performed on the installation surface for installation of the plurality of materials.

Installing the materials on the installation surface may involve processing on the installation surface such as drilling an anchor hole. In this structure, drawing the processing information on the installation surface allows the operator to perform processing on the installation surface without referring to the design drawing, easily improving the working efficiency.

The facility installation management system may further draw, on the installation surface, installation accuracy information indicating installation accuracy for installation of the plurality of materials.

Materials installed on the installation surface may be installed with different accuracy based on, for example, the relationship with the surrounding objects or the structure of the facility. Installing all the materials at high accuracy may lower the working efficiency, whereas installing the materials at an accuracy lower than the specified accuracy may cause interference with other installed objects or failures after the facility starts its operation. In this structure, drawing the installation accuracy information about the installation surface allows the operator to install the materials on the installation surface at appropriate accuracy without referring to the design drawing, easily improving the working efficiency and the installation quality.

When the facility includes a transport device that transports an article using a transport vehicle movable along a predetermined transport path, the facility installation management system may draw a path mark on the installation surface in a manner associated with the installation mark for positioning the transport device. The path mark may indicate at least one of a movement path of the transport vehicle in a curved area of the transport path for the transport device or a movement path of an article transported by the transport vehicle.

When a transport vehicle travels along curves of the rails, the movement path of the profile of the transport vehicle is less easily predictable than when the transport vehicle travels along straight portions. In this structure, the movement path of the transport vehicle is appropriately provided to the operator of the installation work. The transport device can thus be installed on the installation surface to avoid, for example, interference between the transport vehicles and the operator in the facility or interference between the transport articles and other installed objects in the facility.

In the facility installation management system, the installation surface may receive a reference definer to define a three-dimensional reference position. So the reference definer can be placed on the installation surface. The marking device may identify a position of the marking device in a space in which the facility is installed based on a relative position with respect to the reference definer. The marking device may generate installation surface level information indicating a level of the installation surface at a planar position.

The installation surface may have a slight inclination, a slight projection, or a slight depression due to, for example, an error caused when the installation surface is formed, and thus may have a level deviating from the designed reference plane. Generating the installation surface level information during marking reduces the number of remeasurements performed during the installation work, easily improving the efficiency of installing materials during level adjustment.

When the installation surface receives the reference definer and the marking device generates the installation surface level information, the facility installation management system may output a type and a number of adjusters used to install the plurality of materials based on the design drawing of the facility and the installation surface level information.

The design drawing in which materials are arranged on the reference plane includes no adjuster. This structure outputs the type and the number of adjusters to be used based on the installation level information obtained during marking, allowing preparation of adjusters before the start of the installation work, easily improving the efficiency of installation work, and reducing the material cost.

What is claimed is:

1. A facility installation management system for installing a facility,
wherein the system is configured to generate marking information based on a design drawing of the facility, the marking information comprising information indicating marks to be drawn on an installation surface to install a plurality of materials for the facility, the installation surface comprising a surface on which the facility is to be installed, and
wherein the system is configured to draw an identification mark and an installation mark as the marks on the installation surface based on the marking information using a marking device movable along the installation surface, the identification mark indicating identification information identifying each of the plurality of materials, the installation mark indicating at least an installation position of each of the plurality of materials.

2. The facility installation management system according to claim 1, wherein:
the installation mark further indicates at least one of a shape or an orientation of each of the plurality of materials.

3. The facility installation management system according to claim 1, wherein:
the plurality of materials comprise a directly installed material to be installed directly on the installation surface and an indirectly installed material to be attached to the directly installed material, and
the system draws, in a manner associated with the marks indicating the directly installed material, the identification mark indicating the indirectly installed material and quantity information indicating a number of indirectly installed materials to be used.

4. The facility installation management system according to claim 1, wherein:
the system further draws, on the installation surface, processing information indicating information about processing to be performed on the installation surface for installation of the plurality of materials.

5. The facility installation management system according to claim 1, wherein:
the system further draws, on the installation surface, installation accuracy information indicating installation accuracy for installation of the plurality of materials.

6. The facility installation management system according to claim 1, wherein:
the facility comprises a transport device configured to transport an article using a transport vehicle movable along a predetermined transport path, and
the system draws a path mark on the installation surface in a manner associated with the installation mark for positioning the transport device, the path mark indicating at least one of a movement path of the transport vehicle in a curved area of the transport path for the transport device or a movement path of an article transported by the transport vehicle.

7. The facility installation management system according to claim 1, wherein:
the installation surface receives a reference definer to define a three-dimensional reference position,
the marking device identifies a position of the marking device in a space wherein the facility is installed based on a relative position with respect to the reference definer, and
the marking device generates installation surface level information indicating a level of the installation surface at a planar position.

8. The facility installation management system according to claim 7, wherein:
the system outputs a type and a number of adjusters used to install the plurality of materials based on the design drawing of the facility and the installation surface level information.
